(19) United States
(12) Patent Application Publication
(10) Pub. No.: US 2026/0334168 A1
(43) Pub. Date: Oct. 22, 2026

(54) METHOD FOR CONTROLLING OPERATION OF SUBSTRATE PROCESSING APPARATUS, AND SUBSTRATE PROCESSING APPARATUS

(71) Applicant: EBARA CORPORATION, Tokyo (JP)

(72) Inventors: Makoto HAMANO, Tokyo (JP); Ryuya KOIZUMI, Tokyo (JP); Tensei SATO, Tokyo (JP)

(21) Appl. No.: 19/552,940

(22) Filed: Feb. 27, 2026

(30) Foreign Application Priority Data
Mar. 3, 2025 (JP) 2025-033028
Jan. 29, 2026 (JP) 2026-013263

(51) Int. Cl. H10P 74/00; H10P 14/47; H10P 72/00; H10P 74/20

(52) U.S. Cl. CPC H10P 74/238; H10P 14/47; H10P 72/0476; H10P 72/0602; H10P 74/203

(57) ABSTRACT

A method that, even if an abnormal state is detected in a processing module in a substrate processing apparatus including a plurality of processing modules, can suppress deterioration in a throughput of the entire substrate processing apparatus is provided. The method includes a step of controlling the temperature of a chemical using an initial setting value of a target temperature, a step of determining that a processing module in which a temperature measurement value has reached a threshold temperature in a first temperature direction with respect to the initial setting value is in an adjustment required state, a step of controlling, for the processing module in the adjustment required state, the temperature of the chemical using a substitute setting value in a second temperature direction with respect to the initial setting value, a step of determining, for the processing module in the adjustment required state, that, when the temperature measurement value satisfies a predetermined condition, the processing module in the adjustment required state has shifted to a normal state, and a step of executing, for the processing module in the normal state, control for the temperature of the chemical using the initial setting value.

### CROSS REFERENCE TO RELATED APPLICATIONS

This document claims priority to Japanese Patent Application No. 2025-33028, filed Mar. 3, 2025, and Japanese Patent Application No. 2026-13263, filed Jan. 29, 2026, the entire contents of both of which are hereby incorporated by reference.

### BACKGROUND OF THE INVENTION

### Field of the Invention

The present invention relates to a technique for performing substrate processing such as film formation of plating and, more particularly, to a technique for controlling an operation of a substrate processing apparatus configured to perform substrate processing such as film formation of plating on a substrate such as a wafer.

### Description of the Related Art

In a manufacturing process for a device, plating is one of important steps. For example, plating is extensively adopted in order to form microstructures such as wires and bumps (protrusion-shaped metal terminals) of a semiconductor integrated circuit. In recent years, a plating apparatus including a plurality of plating modules disposed in parallel to each perform plating processing on a substrate has been provided. The plating apparatus has an automatic operation function for controlling, based on a production plan, an operation of a robot that carries the substrate into and out from the plating modules and operations of the plating modules. Related art concerning the plating apparatus of this type is disclosed in, for example, Japanese Patent Application Laid-Open No. 2023-127224 (Patent Literature 1).

In the plating apparatus including the plurality of plating modules as explained above, when an abnormal state is detected in a certain plating module among the plurality of plating modules during an automatic operation, an operator needs to check a state of the plating module, eliminate the abnormal state with manual operation, and perform setting for restoring the plating module, the abnormal state of which is eliminated, to an operating state. There is a problem in that such manual operation and setting deteriorate a throughput (the number of substrates for which plating processing is possible per unit time) of the entire plating apparatus. The problem of this type can also occur in substrate processing apparatuses other than the plating apparatus, such as a cleaning apparatus and a wet etching apparatus used in a semiconductor manufacturing process.

### SUMMARY OF INVENTION

In view of the above, an object of the present invention is to provide a method, a substrate processing apparatus, and a computer program that, even if an abnormal state is detected in a processing module in a substrate processing apparatus including a plurality of processing modules such as a plurality of plating modules, can suppress deterioration in a throughput of the entire substrate processing apparatus.

A method according to a first aspect of the present invention is a method for controlling an operation of a substrate processing apparatus including a plurality of processing modules configured to each perform substrate processing on a substrate and a temperature sensor that detects temperature of a chemical in a processing tank included in each of the plurality of processing modules, the method including the steps of: controlling the temperature of the chemical in the processing tank using an initial setting value of a target temperature; determining that, among the plurality of processing modules, a processing module in which a temperature measurement value of the temperature sensor has reached a threshold temperature in a first temperature direction with respect to the initial setting value is in an adjustment required state; controlling, for the processing module in the adjustment required state, the temperature of the chemical in the processing tank using a substitute setting value in a second temperature direction opposite to the first temperature direction with respect to the initial setting value; determining, for the processing module in the adjustment required state, that, when the temperature measurement value of the temperature sensor satisfies a predetermined condition, the processing module in the adjustment required state has shifted to a normal state; and executing, for the processing module in the normal state, control for the temperature of the chemical in the processing tank using the initial setting value.

A substrate processing apparatus according to a second aspect of the present invention includes: the plurality of processing modules; the processing tank included in each of the plurality of processing modules; the temperature sensor; and a control device configured to carry out the method according to the first aspect.

A computer program including a plurality of instructions according to a third aspect of the present invention is a computer program for, when the plurality of instructions are executed by a processor, causing the processor to carry out the method according to the first aspect.

### BRIEF DESCRIPTION OF DRAWINGS

FIG. 1 is a diagram illustrating a schematic configuration of a plating apparatus in an embodiment according to the present invention.

FIG. 2 is a functional block diagram of a control module according to the embodiment.

FIG. 3 is a schematic configuration diagram of a hardware configuration example for implementing the control module according to the embodiment.

FIG. 4 is a sectional view schematically illustrating a configuration of a plating module according to the embodiment.

FIG. 5 is a schematic plan view of a substrate.

FIG. 6 is a flowchart illustrating an example of a schematic procedure of control processing according to the embodiment.

FIG. 7 is a flowchart illustrating a schematic procedure of down processing (step S21) illustrated in FIG. 6.

FIG. 8 is a flowchart illustrating a schematic procedure of down processing (step S22) illustrated in FIG. 6.

FIG. 9 is a flowchart illustrating a schematic procedure of restoration processing (step S32) illustrated in FIG. 6.

FIG. 10 is a flowchart illustrating a schematic procedure of temperature control processing (step S14) illustrated in FIG. 6.

FIG. 11A is a schematic diagram illustrating an example of a relation among an initial setting value of a target temperature, an upper limit threshold temperature, and a lower limit threshold temperature and FIG. 11B is a schematic diagram illustrating an example of a relation among the initial setting value of the target temperature, the upper limit threshold temperature, the lower limit threshold temperature, and a substitute setting value.

FIG. 12 is a diagram illustrating an input/output relation of a trained model used for dynamic determination of the substitute setting value.

### DETAILED DESCRIPTION OF THE PREFERRED EMBODIMENTS

Various embodiments according to the present invention are explained in detail below with reference to the drawings. Note that it is assumed that constituent elements denoted by the same reference numerals and signs in all the drawings have the same configurations and the same functions. Various embodiments for controlling an operation of a plating apparatus are explained below. However, control techniques according to the embodiments can be applied to not only the plating apparatus but also substrate processing apparatuses other than the plating apparatus, such as a cleaning apparatus and a wet etching apparatus used in a semiconductor manufacturing process.

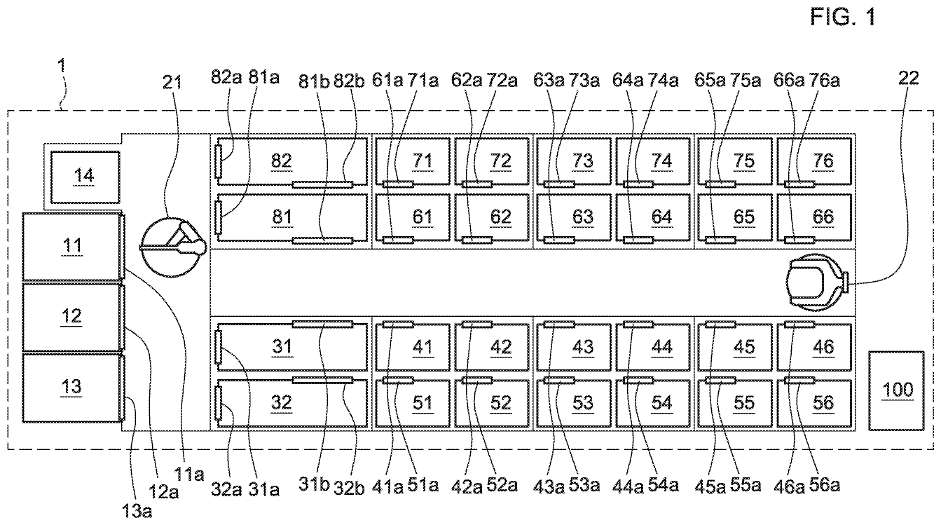

FIG. 1 is a diagram illustrating a schematic configuration of a plating apparatus 1 in an embodiment according to the present invention. In FIG. 1, a plan view of the plating apparatus 1 in the present embodiment viewed from above is illustrated. The plating apparatus 1 includes three load ports 11 to 13, two transfer robots 21 and 22, an aligner 14, two pre-wet modules 31 and 32, twenty-four plating modules 41 to 46, 51 to 56, 61 to 66, and 71 to 76, and a control module 100.

Each of the load ports 11 to 13 is a module for carrying a substrate stored in a not-illustrated cassette such as an FOUP (Front-Opening Unified Pod) into the plating apparatus 1 and carrying the substrate out from the plating apparatus 1 to the cassette. In the present embodiment, the three load ports 11 to 13 are disposed side by side in a row. However, the number and the disposition of the load ports 11 to 13 are not limited thereto and may be optional. One transfer robot 21 is a robot for transferring the substrate and has a function of delivering the substrate among the load ports 11 to 13, the aligner 14, the pre-wet modules 31 and 32, spin rinse modules 81 and 82, and the other transfer robot 22.

The aligner 14 is a module for aligning the positions of an orientation flat and a notch of the substrate with a predetermined direction. In the present embodiment, one aligner 14 is disposed adjacent to the load port 11. However, the number and the disposition of aligners 14 are not limited thereto.

The pre-wet module 31 includes shutters 31a and 31b that are carry in/out ports attached with opening and closing mechanisms. The pre-wet module 32 also includes shutters 32a and 32b that are carry in/out ports attached with opening and closing mechanisms. The transfer robot 21 can carry the substrate into the pre-wet modules 31 and 32 via the shutters 31a and 32a. The transfer robot 22 can carry the substrate out from the pre-wet modules 31 and 32 via the shutters 31b and 32b. Each of the pre-wet modules 31 and 32 is configured to wet a plating surface of the substrate before plating processing with a processing solution such as pure water or degassed water to apply pre-wet processing of replacing air inside a pattern formed on the surface of the substrate with the processing solution. By replacing the processing solution inside the pattern of the substrate with a plating solution (electrolyte solution) at the time of plating, the pre-wet modules 31 and 32 can apply the pre-wet processing to make it easy to supply the plating solution to the inside of the pattern.

As illustrated in FIG. 1, the plating modules 41 to 46, 51 to 56, 61 to 66, and 71 to 76 respectively include shutters 41a to 46a, 51a to 56a, 61a to 66a, and 71a to 76a that are carry in/out ports attached with opening and closing mechanisms. The transfer robot 22 can carry the substrate into the plating modules 41 to 46, 51 to 56, 61 to 66, and 71 to 76 and carry the substrate out from the plating modules 41 to 46, 51 to 56, 61 to 66, and 71 to 76 via the shutters 41a to 46a, 51a to 56a, 61a to 66a, and 71a to 76a.

Each of the plating modules 41 to 46, 51 to 56, 61 to 66, and 71 to 76 is configured to apply the plating processing to the substrate carried thereinto. The plating modules can apply the plating processing to substrates on a single-sheet basis. The number and the disposition of the plating modules 41 to 46, 51 to 56, 61 to 66, and 71 to 76 are not limited to the illustrated ones. The plating modules 41 to 46, 51 to 56, 61 to 66, and 71 to 76 are configured to have the same configuration and the same function for convenience of explanation in the present embodiment but are not limited thereto. A specific configuration example of the plating modules 41 to 46, 51 to 56, 61 to 66, and 71 to 76 is explained below.

The spin rinse module 81 includes shutters 81a and 81b that are carry in/out ports attached with opening and closing mechanisms. The spin rinse module 82 also includes shutters 82a and 82b that are carry in/out ports attached with opening and closing mechanisms. The transfer robot 22 can carry the substrate into the spin rinse modules 81 and 82 via the shutters 81b and 82b. The transfer robot 21 can carry the substrate out from the spin rinse modules 81 and 82 via the shutters 81a and 82a. The spin rinse modules 81 and 82 are modules configured to apply cleaning processing to the substrate in order to remove unnecessary residues such as the plating solution remaining on the substrate after the plating processing and rotate the substrate after the cleaning processing at high speed to dry the substrate. In the present embodiment, two spin rinse modules 81 and 82 are disposed. However, the number and the disposition of the spin rinse modules 81 and 82 are not limited thereto.

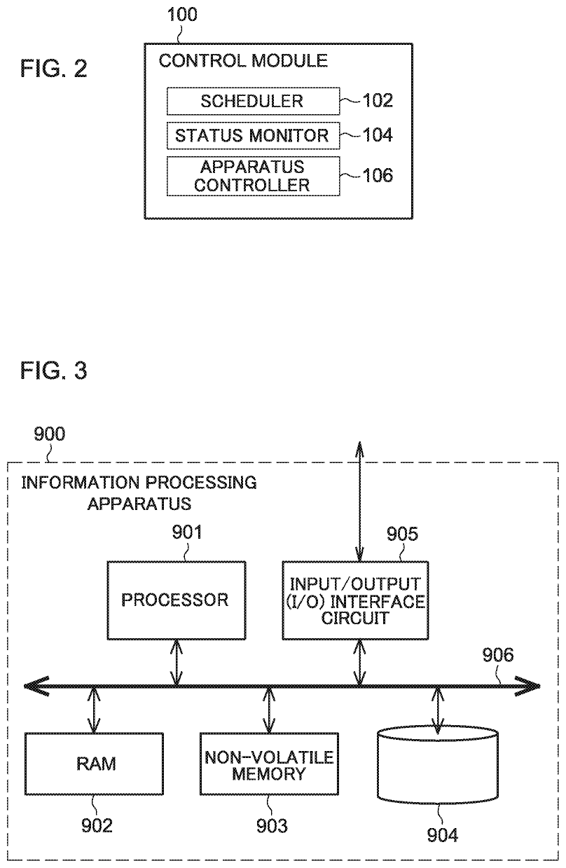

The control module 100 is a control device having an automatic operation function of controlling, based on the production plan, operations of the transfer robots 21 and 22 that carry the substrate into and out from the modules and operations of the modules. FIG. 2 is a functional block diagram of the control module 100. As illustrated in FIG. 2, the control module 100 includes a scheduler 102, a status monitor 104, and an apparatus controller 106. The status monitor 104 has a function of collecting measurement values of various sensor groups in the plating apparatus 1 and generating sensor information representing a state of the plating apparatus 1 such as states of the transfer robots 21 and 22 and the modules from the measurement values. Examples of a sensor group concerning the plating modules include a temperature sensor that detects the temperature of the plating solution in a plating tank, a liquid surface sensor that detects the height of a liquid surface of the plating solution in the plating tank, a concentration sensor that detects the concentration of the plating solution, a pH sensor that measures a pH value of the plating solution, a pressure sensor that measures the pressure of a chemical such as the plating solution, a position sensor that detects disposition of the substrate, a film thickness sensor that detects the thickness of a plating film, and a sensor that measures a voltage and an electric current of a rectifier.

The scheduler 102 can create a processing schedule from the production plan and generate, based on the processing schedule, a command for controlling operation states of the transfer robots 21 and 22 and operation states of the modules. The apparatus controller 106 can control the operation states of the transfer robots 21 and 22 and the operation states of the modules according to the command generated by the scheduler 102. The scheduler 102 can also dynamically adjust, based on the sensor information, the processing schedule according to a current operation status of the plating apparatus 1.

For example, the control module 100 only has to be configured by a computer operable by an operator and desirably includes user interface equipment such as a pointing device and a key input device to enable the operator to input information.

The control module 100 explained above may be implemented by one computer including one or more processors or may be implemented by a plurality of computers connected to one another via a communication path. All or some of constituent elements of the control module 100 only have to be implemented by one or more processors including one or more arithmetic devices (processing units) that execute processing by codes (a plurality of instructions) of software or firmware read from a non-volatile memory (a computer-readable recording medium). For example, as the arithmetic device, a CPU (Central Processing Unit), a GPU (Graphics Processing Unit), or an NPU (Neural Network Processing Unit) can be used. The GPU and the NPU are arithmetic devices designed to have structure suitable to an arithmetic operation (for example, a tensor operation) that is based on an artificial neural network (ANN), that is, a neural network model (NN model). Alternatively, all or some of the constituent elements of the control module 100 can be implemented by one or more processors including a semiconductor integrated circuit such as an FPGA (Field-Programmable Gate Array). Alternatively, all or some of the constituent elements of the control module 100 may be implemented by one or more processors including a combination of the semiconductor integrated circuit such as the FPGA and the arithmetic device such as the CPU or the GPU.

FIG. 3 is a schematic configuration diagram of an information processing apparatus (a computer) 900 that is a hardware configuration example for implementing the control module 100. The information processing apparatus 900 includes a processor 901, a random access memory (RAM) 902, a non-volatile memory 903, a large capacity storage 904, an input/output (I/O) interface circuit 905, and a signal path 906. The signal path 906 is a bus for connecting the processor 901, the RAM 902, the non-volatile memory 903, the storage 904, and the input/output (I/O) interface circuit 905 to one another. The RAM 902 is a data storage region used when the processor 901 executes digital signal processing. When the processor 901 incorporates the arithmetic device such as the CPU or the GPU, the non-volatile memory 903 can include a data storage region where codes of software to be executed by the processor 901 are stored. For example, the input/output (I/O) interface circuit 905 is connectable to not-illustrated user interface equipment.

Next, an example of plating processing by the plating apparatus 1 is explained. First, a substrate stored in a cassette is carried into any one load port among the load ports 11 to 13. Subsequently, the transfer robot 21 takes out the substrate from the cassette of the load port and transfers the substrate to the aligner 14. The aligner 14 aligns the positions of an orientation flat and a notch of the substrate with a predetermined direction. The transfer robot 21 carries the substrate, the position of which is aligned by the aligner 14, into any one pre-wet module of the pre-wet modules 31 and 32. The pre-wet module applies pre-wet processing to the substrate. The transfer robot 22 carries the substrate, to which the pre-wet processing is applied, into any one plating module among the plating modules 41 to 46, 51 to 56, 61 to 66, and 71 to 76. The plating module applies plating processing to the carried-in substrate.

Thereafter, the transfer robot 22 carries the substrate, to which the plating processing is applied, into any one spin rinse module of the spin rinse modules 81 and 82. The spin rinse module applies cleaning processing and drying processing to the carried-in substrate. The transfer robot 21 carries the substrate out from the spin rinse module and transfers the substrate to a cassette present in any one load port among the load ports 11 to 13. Finally, the cassette storing the substrate is carried out from the load port.

Next, a configuration example of the plating modules 41 to 46, 51 to 56, 61 to 66, and 71 to 76 is explained.

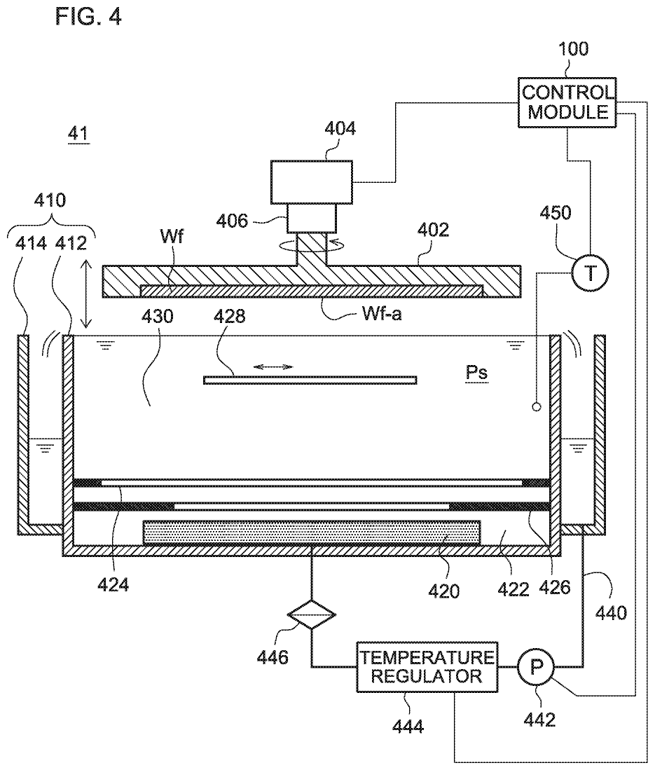

Since the twenty-four plating modules 41 to 46, 51 to 56, 61 to 66, and 71 to 76 in the present embodiment have the same configuration, only one plating module 41 is explained. FIG. 4 is a sectional view schematically illustrating a configuration of the plating module 41. As illustrated in FIG. 4, the plating module 41 includes a plating tank 410 for storing a plating solution Ps. The plating tank 410 includes a cylindrical inner tank 412 opened in an upper surface and an outer tank (an overflow tank) 414 provided around the inner tank 412 to be able to store a plating solution overflowing from the upper edge of the inner tank 412.

The plating module 41 includes a substrate holder 402 for holding a substrate Wf having a plating surface Wf-a. As illustrated in FIG. 4, the substrate holder 402 is configured to grasp the outer edge portion of the substrate Wf in a state in which the plating surface Wf-a is directed in the direction of the opening of the plating tank 410. The plating module 41 includes a lifting mechanism 404 for lifting and lowering the substrate holder 402. In the embodiment, the plating module 41 includes a rotation mechanism 406 that rotates the substrate holder 402 around the vertical axis. The lifting mechanism 404 and the rotation mechanism 406 can be implemented by, for example, a publicly-known mechanism such as a motor. At the time of plating processing, the lifting mechanism 404 lowers the substrate holder 402 and immerses the plating surface Wf-a of the substrate Wf in the plating solution Ps.

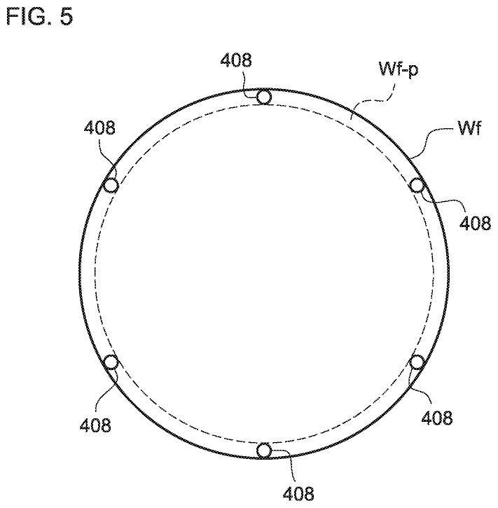

The substrate holder 402 includes one or more electrical contacts for feeding power from a not-illustrated power supply to the substrate Wf in a state in which the plating surface Wf-a is immersed in the plating solution Ps. FIG. 5 is a schematic plan view of the substrate Wf. An outer edge portion Wf-p of the substrate Wf is also a portion where the substrate Wf is gripped by the substrate holder 402. In an example illustrated in FIG. 5, the outer edge portion Wf-p of the substrate Wf includes six electrical contacts 408 provided at equal intervals in the circumferential direction of the substrate Wf. However, the number of the electrical contacts 408 is not limited to six. The electrical contacts 408 are connected to negative terminals of the power supply via electric wires (not illustrated) built in the inside of the substrate holder 402. An electric current for plating can be fed to the substrate Wf through the electrical contacts 408.

Referring to FIG. 4, the plating module 41 includes an anode 420 provided on the bottom surface of the inner tank 412. The anode 420 is disposed in the inner tank 412 to face the plating surface Wf-a of the substrate Wf held by the substrate holder 402. The plating module 41 includes a membrane 424 that partitions an inner region of the inner tank 412 into an upper region and a lower region. That is, the inner region of the inner tank 412 is divided into, by the membrane 424, a cathode region 430 relatively close to the plating surface Wf-a and an anode region 422 relatively close to the anode 420. The plating solution Ps is filled in the cathode region 430 and the anode region 422, respectively. Note that, in the present embodiment, an example in which the membrane 424 is provided is explained. However, a form in which the membrane 424 is not provided is also possible.

An anode mask 426 for adjusting electrolytic conditions between the anode 420 and the substrate Wf is disposed in the anode region 422. The anode mask 426 is, for example, a substantially plate-shaped member made of a dielectric material and is provided on the front surface side (above) the anode 420. The anode mask 426 includes an opening through which an electric current flowing between the anode 420 and the substrate Wf passes. In the present embodiment, the anode mask 426 is configured such that an opening dimension can be changed. The opening dimension of the anode mask 426 can be variably adjusted by the control module 100. Note that, as means for variably adjusting the opening dimension in the anode mask 426, a publicly-known mechanism can be adopted. In the present embodiment, an example in which the anode mask 426 is provided is explained. However, a form in which the anode mask 426 is not provided is also possible. In an example illustrated in FIG. 4, the membrane 424 and the anode mask 426 are provided to be spatially separated. However, instead, the membrane 424 may be provided in the opening of the anode mask 426.

A paddle 428 for stirring the plating solution Ps is provided in a region close to the surface of the substrate Wf in the cathode region 430. The paddle 428 can be made of, for example, titanium (Ti) or resin. By reciprocating (for example, in a direction parallel to the plating surface Wf-a of the substrate Wf), the paddle 428 can stir the plating solution such that sufficient metal ions are uniformly supplied to the plating surface Wf-a during plating of the substrate Wf. Note that a form in which the paddle 428 is not provided in the plating module 41 is also possible.

The plating module 41 includes, as structure for circulating the plating solution, a liquid circulation line 440 extending from the outer tank 414 to the inner tank 412, a circulation pump 442, a temperature regulator 444, and a filter 446. One end of the liquid circulation line 440 is connected to the bottom of the outer tank 414. The other end of the liquid circulation line 440 is connected to the bottom of the inner tank 412. The liquid circulation line 440 includes the circulation pump 442, the temperature regulator 444, and the filter 446. Since the liquid circulation line 440 is configured to circulate the plating solution in the outer tank 414 and blow out the plating solution into the inner tank 412, the plating solution Ps in the inner tank 412 always overflows the sidewall of the inner tank 412 and flows into the inner tank 412. In this way, the plating solution circulates in the liquid circulation line 440, the inner tank 412, and the outer tank 414. The temperature regulator 444 of the liquid circulation line 440 includes a heating and cooling device and can control the temperature of the circulating plating solution to be closer to a target temperature. The control module 100 can set a setting value of the target temperature in the temperature regulator 444 to any value.

The plating module 41 includes a temperature sensor 450 that detects the temperature of the plating solution Ps in the plating tank 410 and outputs a temperature detection value (instantaneous value). The control module 100 can monitor the temperature detection value output from the temperature sensor 450 and determine whether an abnormal state has occurred in the plating module 41.

Next, the plating processing in the plating module 41 in the present embodiment is explained.

In the plating processing, the substrate Wf is immersed in the plating solution in the cathode region 430 using the lifting mechanism 404, whereby the substrate Wf is exposed to the plating solution. The plating module 41 can apply the plating processing to the plating surface Wf-a of the substrate Wf by applying a voltage between the anode 420 and the substrate Wf in this state. A conductive film (a plating film) is deposited on the plating surface Wf-a of the substrate Wf by the plating processing. In the embodiment, the plating processing may be performed while rotating the substrate holder 402 using the rotation mechanism 406.

The control module 100 may execute adjustment of conditions of the plating processing, that is, plating conditions when another substrate Wf is plated after the current plating processing is completed or may execute, in real time, adjustment of plating conditions in the current plating processing. For example, the control module 100 may adjust the plating conditions in real time by driving the lifting mechanism 404 to adjust the position of the substrate Wf. The control module 100 can also adjust the plating conditions in real time by adjusting the opening dimension of the anode mask 426.

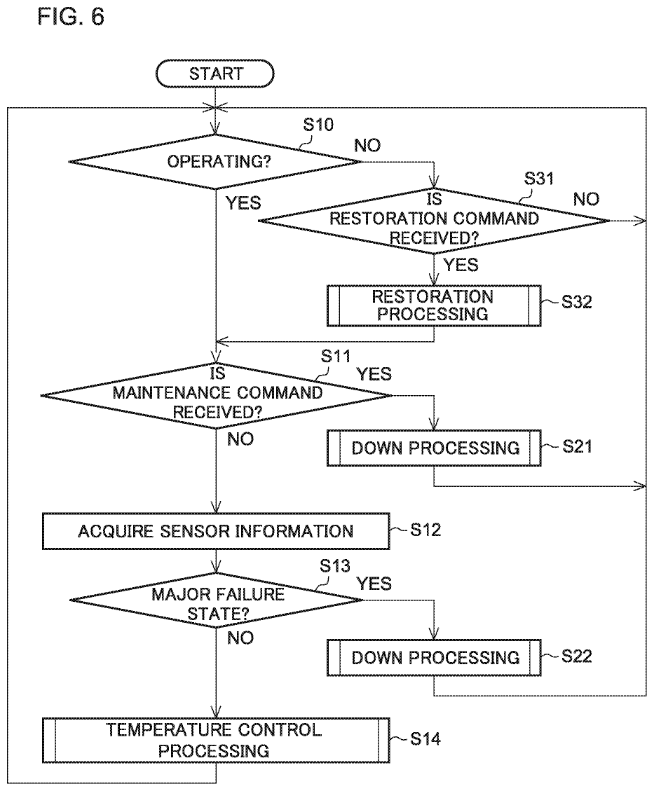

Next, a method for controlling an operation during an automatic operation of the plating apparatus 1 in the present embodiment is explained in detail with reference to FIGS. 6 to 10. In the plating apparatus 1 during the automatic operation, the apparatus controller 106 of the control module 100 can cause a plurality of plating modules among the plating modules 41 to 46, 51 to 56, 61 to 66, and 71 to 76 illustrated in FIG. 1 to simultaneously operate in parallel according to a processing schedule determined by the scheduler 102.

FIG. 6 is a flowchart illustrating an example of a schematic procedure of control processing according to the embodiment. FIG. 6 illustrates a procedure of control processing for one plating module set as a control target. The control module 100 can simultaneously execute the control processing illustrated in FIG. 6 in parallel respectively on the plurality of plating modules 41 to 46, 51 to 56, 61 to 66, and 71 to 76.

Referring to FIG. 6, the control module 100 determines whether the plating module set as the control target is operating (step S10). When the plating module is operating (YES in step S10), the control module 100 determines whether a maintenance command is received for the plating module (step S11). The maintenance command is a command generated by the operator operating (for example, pressing a button of) the user interface equipment of the plating apparatus 1. For example, the operator can designate, as a maintenance target, a specific plating module 41 among the operating plating modules 41 to 46, 51 to 56, 61 to 66, and 71 to 76. When receiving the maintenance command (YES in step S11), the scheduler 102 of the control module 100 executes down processing of excluding the plating module designated by the maintenance command from the processing schedule and bringing the plating module into a nonoperating state (step S21).

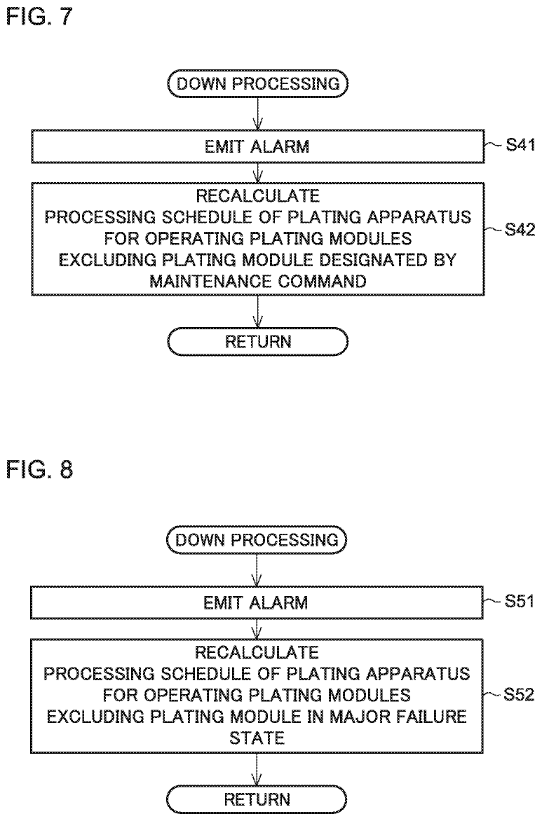

FIG. 7 is a flowchart illustrating a schematic procedure of the down processing in step S21. Referring to FIG. 7, first, the control module 100 emits an alarm for the plating module designated by the maintenance command (step S41). For example, the control module 100 can notify, with image display or acoustic output through user interface equipment such as a display device or a speaker, the operator of information for specifying the plating module being maintained (for example, an allocation number or a name of the plating module).

After step S41, the scheduler 102 recalculates a processing schedule of the plating apparatus 1 for operating plating modules excluding the plating module designated by the maintenance command (step S42). The scheduler 102 generates a command based on the recalculated processing schedule. The apparatus controller 106 controls, according to the command, operation states of the transfer robots 21 and 22 and operation states of the modules (excluding the plating module designated by the maintenance command). Accordingly, the plating module designated by the maintenance command is excluded from the recalculated processing schedule and comes into the nonoperating state. After the down processing explained above, the procedure of the control processing returns to step S10 in FIG. 6.

Referring to FIG. 6, when not receiving the maintenance command (NO in step S11), the control module 100 acquires sensor information from the status monitor 104 (step S12) and determines, based on the sensor information, whether the plating module set as the control target is in a major failure state (step S13). Here, the major failure state is an abnormal state in which the plating module cannot perform plating processing on the substrate. For example, a state in which loading of the substrate cannot be performed because of a failure of a movable portion such as the lifting mechanism in the plating module and a state in which an electric current for plating cannot be supplied because of a failure of a rectifier correspond to the major failure state. Examples of the state in which loading of the substrate cannot be performed include a state in which the shutter 41a of the plating module 41 illustrated in FIG. 1 does not operate and the transfer robot 22 cannot carry in and out the substrate and a state in which transfer, positioning, or fixing of the substrate cannot be performed in the plating module 41.

When it is determined that the plating module is in the major failure state (YES in step S13), the scheduler 102 executes the down processing of excluding the plating module in the major failure state from the processing schedule and bringing the plating module into the nonoperating state (step S22).

FIG. 8 is a flowchart illustrating a schematic procedure of the down processing in step S22. Referring to FIG. 8, first, the control module 100 emits an alarm for the plating module in the major failure state (step S51). For example, the control module 100 can notify, with image display or acoustic output through the user interface equipment such as the display device or the speaker, the operator of information for specifying the plating module in the major failure state (for example, an allocation number or a name of the plating module).

After step S51, the scheduler 102 recalculates a processing schedule of the plating apparatus 1 for operating plating modules excluding the plating module in the major failure state (step S52). The scheduler 102 generates a command based on the recalculated processing schedule. The apparatus controller 106 controls operation states of the transfer robots 21 and 22 and operation states of the modules (excluding the plating module in the major failure state) according to the command. Accordingly, the plating module in the major failure state is excluded from the recalculated processing schedule and comes into the nonoperating state. After the down processing explained above, the procedure of the control processing returns to step S10 in FIG. 6.

Referring to FIG. 6, when determining in step S10 that the plating module is not operating (NO in step S10), the control module 100 determines whether a restoration command is received for the plating module (step S31). The restoration command is a command generated by the operator operating (for example, pressing a button of) the user interface equipment of the plating apparatus 1. For example, the operator can set the plating module, the major failure state of which is resolved by repairing, as a target of the restoration command. When the restoration command is not received (NO in step S31), the procedure of the control processing returns to step S10. On the other hand, when the restoration command is received (YES in step S31), the scheduler 102 of the control module 100 executes restoration processing of incorporating the plating module designated by the restoration command in the processing schedule and bringing the plating module into an operating state (step S32).

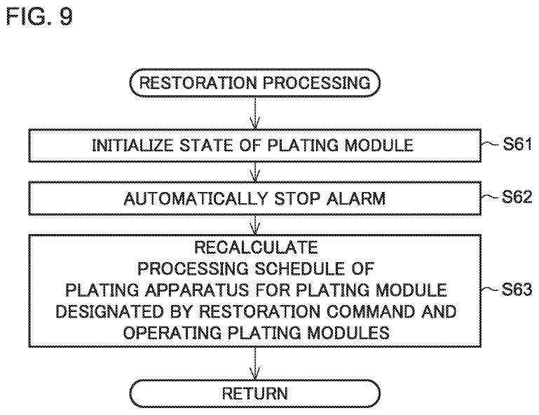

FIG. 9 is a flowchart illustrating a schematic procedure of the restoration processing in step S32. Referring to FIG. 9, first, the control module 100 initializes a state of the plating module designated by the restoration command (step S61). At this time, the control module 100 only has to execute origin returning processing of returning the movable portion such as the lifting mechanism in the plating module to a predetermined reference position (origin). The control module 100 automatically stops the alarm (step S62). At this time, the control module 100 can notify, with image display or acoustic output through the user interface equipment such as the display device or the speaker, the operator of information for specifying the plating module (for example, an allocation number or a name of the plating module).

Thereafter, the scheduler 102 recalculates a processing schedule of the plating apparatus 1 for the plating module designated by the restoration command and the operating plating modules (step S63). The scheduler 102 generates a command based on the recalculated processing schedule. The apparatus controller 106 controls operation states of the transfer robots 21 and 22 and operation states of the modules according to the command. Accordingly, the plating module designated by the restoration command is incorporated in the recalculated processing schedule and comes into the operating state. After the restoration processing explained above, the procedure of the control processing shifts to step S11 in FIG. 6.

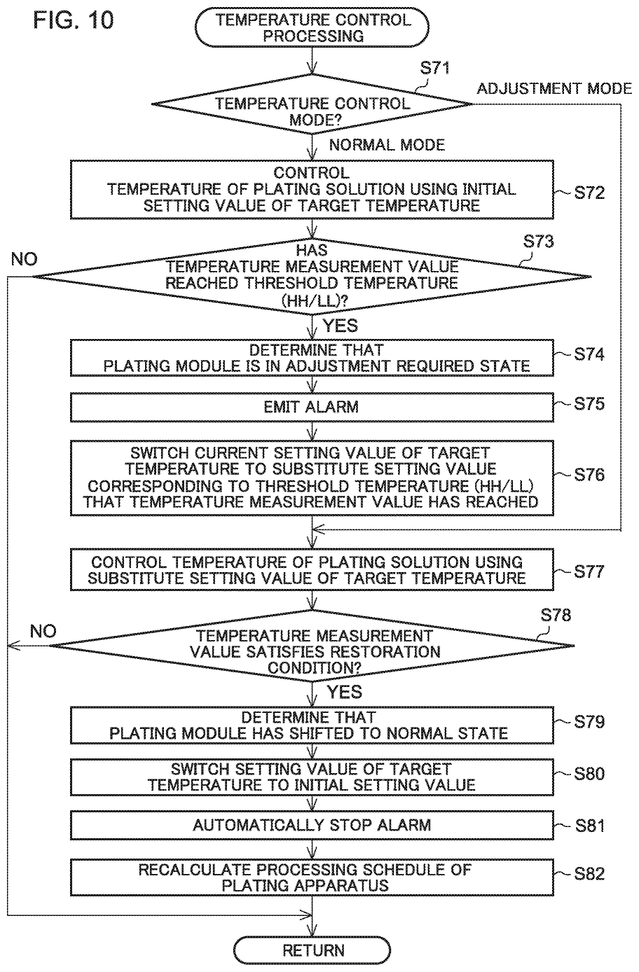

Referring to FIG. 6, in step S12, the control module 100 acquires sensor information. When determining that the plating module set as the control target is not in the major failure state (NO in step S13), the control module 100 executes temperature control processing (step S14). FIG. 10 is a flowchart illustrating a schematic procedure of the temperature control processing in step S14.

Referring to FIG. 10, the apparatus controller 106 of the control module 100 determines which of a normal mode and an adjustment mode a temperature control mode is (step S71). When the temperature control mode is the normal mode, the apparatus controller 106 controls, based on a temperature measurement value Tc, the temperature of the plating solution in the plating tank using an initial setting value T0 of a target temperature (step S72). At this time, the apparatus controller 106 can control the temperature of the plating solution in the plating tank to be closer to the initial setting value T0 by setting a setting value of a target temperature in a temperature regulator of a liquid circulation line of the plating module (for example, the temperature regulator 444 of the liquid circulation line 440 in FIG. 4) to the initial setting value T0. Note that means for controlling the temperature of the plating solution is not limited to the temperature regulator of the liquid circulation line and another temperature regulator may be used.

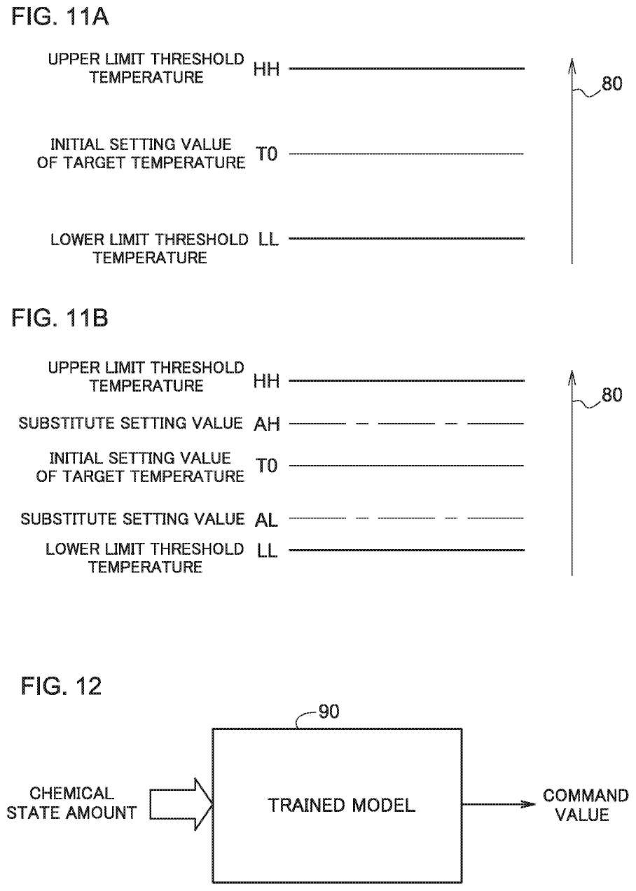

Subsequently, the control module 100 determines, based on sensor information, whether the temperature measurement value Tc of the plating solution in the plating module has reached a threshold temperature HH/LL (step S73). As the temperature measurement value Tc, a moving average of temperatures (temperature detection values) continuously detected by a temperature sensor (for example, the temperature sensor 450 in FIG. 4) can be used. Here, the threshold temperature is a threshold for determining an allowable temperature range and is an upper limit threshold temperature HH and a lower limit threshold temperature LL. As explained above, in the normal mode, the apparatus controller 106 executes feedback control for bringing the temperature measurement value Tc of the temperature sensor closer to the initial setting value T0 of the target temperature such that the temperature of the plating solution falls within the allowable temperature range. The upper limit threshold temperature HH is a threshold temperature that is, with respect to the initial setting value T0, in a temperature direction in which the temperature of the plating solution rises. The lower limit threshold temperature LL is a threshold temperature that is, with respect to the initial setting value T0, in a temperature direction in which the temperature of the plating solution drops. FIG. 11A is a schematic diagram illustrating an example of a relation among the initial setting value T0 of the target temperature, the upper limit threshold temperature HH, and the lower limit threshold temperature LL. In the example illustrated in FIG. 11A, a direction 80 indicates the temperature direction in which the temperature of the plating solution rises and a direction opposite to the direction 80 indicates the temperature direction in which the temperature of the plating solution drops.

When the temperature measurement value Tc of the plating solution has not reached the threshold temperature HH/LL (NO in step S73), the procedure of the control processing returns to step S10 in FIG. 6.

On the other hand, when the temperature measurement value Tc of the plating solution in the plating module has reached the threshold temperature HH/LL (YES in step S73), the control module 100 determines that the plating module is in the adjustment required state (step S74). Accordingly, the control mode for the plating module determined as being in the adjustment required state is switched from the normal mode to the adjustment mode. Subsequently, the control module 100 emits an alarm (step S75). At this time, for example, the control module 100 can notify, with image display or acoustic output through the user interface equipment such as the display device or the speaker, the operator of information for specifying the plating module determined as being in the adjustment required state (for example, an allocation number or a name of the plating module).

Here, the adjustment required state is a relatively light abnormal state not reaching the major failure state concerning the temperature of the plating solution. For example, when a concentration abnormality of the plating solution in the plating tank or an abnormality of a chemical amount occurs during an automatic operation, the temperature of the plating solution sometimes reaches the threshold temperature HH/LL. Even in such a case, the abnormal state can be resolved by adjusting the temperature of the plating solution in the plating module early.

In step S76, the control module 100 switches a current setting value of the target temperature to a substitute setting value corresponding to the threshold temperature HH/LL that the temperature measurement value Tc has reached. Specifically, when the temperature measurement value Tc has reached the upper limit threshold temperature HH, the control module 100 only has to switch the setting value to a substitute setting value AL that is, with respect to the initial setting value T0, in the temperature direction in which the temperature drops opposite to the direction in which the temperature rises. For example, if an initial setting value is 23 °C, the control module 100 can switch the setting value to the substitute setting value AL of 21 °C (=23 °C−2 °C). On the other hand, when the temperature measurement value Tc has reached the lower limit threshold temperature LL, the control module 100 only has to switch the setting value to a substitute setting value AH that is, with respect to the initial setting value T0, in the temperature direction in which the temperature rises opposite to the direction in which the temperature drops. For example, if the initial setting value T0 is 23 °C, the control module 100 can switch the setting value to the substitute setting value AH of 26 °C (=23 °C+3 °C). FIG. 11B is a schematic diagram illustrating an example of a relation among the initial setting value T0 of the target temperature, the upper limit threshold temperature HH, the lower limit threshold temperature LL, and the substitute setting values AH and AL. Note that, in the example illustrated in FIG. 11B, the substitute setting value AL is set between the initial setting value T0 and the lower limit threshold temperature LL and the substitute setting value AH is set between the initial setting value T0 and the upper limit threshold temperature HH. However, the substitute setting value AL and the substitute setting value AH are not limited thereto. Alternatively, the substitute setting value AL can be set to a value lower than the lower limit threshold temperature LL and/or the substitute setting value AH can be set to a value higher than the upper limit threshold temperature HH.

After the setting value of the target temperature is switched (step S76), the apparatus controller 106 controls, based on the temperature measurement value Tc, the temperature of the plating solution in the plating tank using the substitute setting value of the target temperature (step S77).

Thereafter, the control module 100 determines whether the temperature measurement value Tc satisfies a predetermined restoration condition (step S78) and, if the temperature measurement value Tc does not satisfy the restoration condition (NO in step S78), returns the procedure of the control processing to step S10 in FIG. 6. For example, as the restoration condition, a condition that the temperature measurement value Tc has reached the initial setting value T0 or a setting value near the initial setting value T0 only has to be adopted.

After the procedure of the control processing returns to step S10 in FIG. 6, when the temperature control processing in FIG. 10 is started again, if it is determined that the temperature control mode is the adjustment mode (step S71), the processing in step S77 and subsequent steps is executed.

If the temperature measurement value Tc satisfies the restoration condition in step S78 (YES in step S78), the control module 100 determines that the plating module has shifted from the adjustment required state to the normal state (step S74). Accordingly, the control mode for the plating module is switched from the adjustment mode to the normal mode. Then, the control module 100 switches the setting value of the target temperature to the initial setting value T0 (step S80). Subsequently, the control module 100 automatically stops the alarm (step S81). At this time, the control module 100 can notify, with image display or acoustic output through the user interface equipment such as the display device or the speaker, the operator of information for specifying the plating module (for example, an allocation number or a name of the plating module).

Thereafter, the scheduler 102 recalculates a processing schedule of the plating apparatus 1 for the plating module that has returned to the normal state and the operating plating modules (step S82). The scheduler 102 generates a command based on the recalculated processing schedule. The apparatus controller 106 controls, according to the command, operation states of the transfer robots 21 and 22 and operation states of the modules. Accordingly, the plating module that has returned to the normal state is incorporated in the recalculated processing schedule and comes into the operating state. After the temperature control processing explained above, the procedure of the control processing returns to step S10 in FIG. 6.

As explained above, with the control method in the present embodiment, when it is determined that a certain plating module among the operating plurality of plating modules is in the major failure state (YES in step S13 in FIG. 6), the down processing of excluding the plating module from the recalculated processing schedule and bringing the plating module into the nonoperating state is performed (steps S51 and S52 in FIG. 8). On the other hand, when determining that a certain plating module among the operating plurality of plating modules is in a relatively light abnormal state not reaching the major failure state concerning the temperature of the plating solution (steps S72 to S74 in FIG. 10), the control module 100 does not execute the down processing and switches the setting value of the target temperature to a substitute setting value and executes the temperature control using the substitute setting value (steps S76 and S77) and performs recalculation (rescheduling) of a processing schedule (step S82). Accordingly, it is possible to resolve the abnormal state early and return the plating module to the normal state. Therefore, it is possible to suppress deterioration in a throughput of the entire plating apparatus 1 during the automatic operation.

The control technique according to the embodiment explained above can be applied to not only the plating apparatus but also substrate processing apparatuses such as a plating apparatus, a cleaning apparatus, and a wet etching apparatus used in a semiconductor manufacturing process. In general, the substrate processing apparatus includes a plurality of processing modules (for example, plating modules) and is configured to execute substrate processing (for example, plating processing) on a substrate in a processing tank (for example, a plating tank) of a processing module.

In the control method explained above, the control module 100 has a function of determining a substitute setting value. The substitute setting value only has to be stored in a memory (for example, the non-volatile memory 903 in FIG. 3) in advance or calculated based on a predetermined value stored in the memory. Alternatively, the substitute setting value may be dynamically (that is, adaptively) determined according to an operation state of the substrate processing apparatus such as the plating apparatus 1 using a trained model such as a neural network model (NN model) trained by known machine learning. As the machine learning (ML), supervised learning, semi-supervised learning, or reinforcement learning can be used. The trained model may be incorporated in the control module 100 or may be provided in a form of being disposed outside the control module 100 and called from the control module 100.

When the trained model is configured by the NN model, as the NN model, for example, a feedforward NN (Feedforward Neural Network), an RNN (Recurrent Neural Network), an LSTM (Long Short-Term Memory), a GRU (Gated Recurrent Unit), a Bi-LSTM (Bidirectional LSTM), a Bi-RNN (Bidirectional RNN), a CNN (Convolutional Neural Network), and/or a transformer having an attention mechanism can be used.

FIG. 12 is a diagram for explaining a trained model 90 used to dynamically determine a substitute setting value. As illustrated in FIG. 12, the trained model 90 is trained to, when receiving a chemical state amount (input data) representing a state of a chemical such as a plating solution or a cleaning solution in the substrate processing apparatus, execute inference processing that is based on the input data to thereby output a command value (output data) that is a result of the inference processing. The command value is a value corresponding to the substitute setting value AH/AL. The trained model 90 can be trained such that the command value is, for example, a real number value in a range of −1 to +1. The control module 100 can determine, using the trained model 90, in real time, the substitute setting value AH/AL corresponding to the command value output from the trained model 90.

The chemical state amount input to the trained model 90 only has to be a scalar amount or a vector amount including at least the temperature measurement value Tc. The chemical state amount may further include at least one of the following input data elements (1) to (9).
(1) A temperature difference between the current target temperature and the temperature measurement value Tc,
(2) A temporal change rate (a differential value) or a temporal change amount of the temperature measurement value Tc,
(3) A temperature difference between the initial setting value T0 and the temperature measurement value Tc,
(4) A temperature difference between the initial setting value T0 and the temperature measurement value Tc,
(5) A temperature difference between the upper limit threshold temperature HH and the temperature measurement value Tc,
(6) A temperature difference between the lower limit threshold temperature LL and the temperature measurement value Tc,
(7) A value indicating a type of a chemical,
(8) Concentration of the chemical, and
(9) A circulation liquid amount of the chemical.

Note that the input data to the trained model 90 may further include an apparatus state amount representing a state of the substrate processing apparatus, such as an area of the plating surface of the substrate.

The trained model 90 is desirably trained by reinforcement learning. As a known reinforcement learning algorithm, for example, PPO (Proximal Policy Optimization), SAC (Soft Actor-Critic), TD3 (Twin Delayed DDPG), DDPG (Deep Deterministic Policy Gradient), A3C (Asynchronous Advantage Actor-Critic), TRPO (Trust Region Policy Optimization), or DON (Deep Q-Network) can be used. However, the reinforcement learning algorithm is not limited thereto.

A reward function used in the reinforcement learning can be designed to, for example, output a reward of a fixed value (for example, zero) when the temperature measurement value Tc is within the allowable temperature range (LL to HH), output a reward of a value (for example, a negative value) that is lower as the temperature measurement value Tc exceeds the allowable temperature range and is further away from the upper limit value HH to a high temperature side, and output a reward of a value (for example, a negative value) that is lower as the temperature measurement value Tc exceeds the allowable temperature range and is further away from the lower limit value LL to a low temperature side but is not limited thereto. The reinforcement learning algorithm is executed to maximize or minimize an evaluation function based on a reward (an instantaneous evaluation value) calculated using the reward function. For example, as the evaluation function, a function designed to output an expectation value of a cumulative reward defined using a discount factor only has to be used.

It should be understood that changes, additions, and improvements of the embodiment explained above can be performed as appropriate without departing from the gist and the scope of the present invention. The scope of the present invention should be interpreted based on the description of the claims and should be understood as further including equivalents of the claims.

1. A method for controlling an operation of a substrate processing apparatus including a plurality of processing modules configured to each perform substrate processing on a substrate and a temperature sensor that detects temperature of a chemical in a processing tank included in each of the plurality of processing modules, the method comprising the steps of:
controlling the temperature of the chemical in the processing tank using an initial setting value of a target temperature;
determining that, among the plurality of processing modules, a processing module in which a temperature measurement value of the temperature sensor has reached a threshold temperature in a first temperature direction with respect to the initial setting value is in an adjustment required state;
controlling, for the processing module in the adjustment required state, the temperature of the chemical in the processing tank using a substitute setting value in a second temperature direction opposite to the first temperature direction with respect to the initial setting value;
determining, for the processing module in the adjustment required state, that, when the temperature measurement value of the temperature sensor satisfies a predetermined condition, the processing module in the adjustment required state has shifted to a normal state; and
executing, for the processing module in the normal state, control for the temperature of the chemical in the processing tank using the initial setting value.

2. The method according to claim 1, further comprising a step of determining the substitute setting value using a trained model trained by machine learning, wherein
the trained model is configured to, when receiving, as input data, a chemical state amount representing a state of the chemical, execute inference processing that is based on the input data and output the substitute setting value or a command value corresponding to the substitute setting value, and
the chemical state amount includes at least the temperature measurement value.

3. The method according to claim 2, wherein the trained model is a neural network model.

4. The method according to claim 1, wherein the first temperature direction is a direction in which the temperature of the chemical rises or a direction in which the temperature of the chemical drops.

5. The method according to claim 4, wherein the threshold temperature is temperature higher than the initial setting value, and the substitute setting value is a value lower than the initial setting value.

6. The method according to claim 4, wherein the threshold temperature is temperature lower than the initial setting value, and the substitute setting value is a value higher than the initial setting value.

7. The method according to claim 1, wherein the temperature measurement value is a moving average of temperatures continuously detected by the temperature sensor.

8. The method according to claim 1, further comprising a step of, after the processing module in the adjustment required state has shifted to the normal state, recalculating a processing schedule of the substrate processing apparatus for the plurality of processing modules.

9. The method according to claim 1, further comprising the steps of:
receiving a restoration command designating at least one processing module among the plurality of processing modules; and
recalculating a processing schedule of the substrate processing apparatus for a plurality of processing modules including the designated processing module.

10. The method according to claim 1, wherein the substrate processing apparatus is a plating apparatus, the chemical is a plating solution, the substrate processing is plating processing, the processing module is a plating module, and the processing tank is a plating tank.

11. A substrate processing apparatus comprising:
the plurality of processing modules;
the processing tank included in each of the plurality of processing modules;
the temperature sensor; and
a control device configured to carry out the method according to claim 1.

12. A computer-readable non-transitory storage medium comprising a computer program including a plurality of instructions, the computer program causing, when the plurality of instructions are executed by a processor, the processor to carry out the method according to claim 1.

13. The method according to claim 2, wherein the substrate processing apparatus is a plating apparatus, the chemical is a plating solution, the substrate processing is plating processing, the processing module is a plating module, and the processing tank is a plating tank.

14. A substrate processing apparatus comprising:
the plurality of processing modules;
the processing tank included in each of the plurality of processing modules;
the temperature sensor; and
a control device configured to carry out the method according to claim 2.

15. A computer-readable non-transitory storage medium comprising a computer program including a plurality of instructions, the computer program causing, when the plurality of instructions are executed by a processor, the processor to carry out the method according to claim 2.
